(19) United States
(12) Patent Application Publication
(10) Pub. No.: US 2011/0211382 A1
(43) Pub. Date: Sep. 1, 2011

(54) HIGH DENSITY AND LOW VARIABILITY READ ONLY MEMORY

(75) Inventors: Ashish SHARMA, New Delhi (IN); Bikas Maiti, Austin, TX (US); Manmohan Rana, Ghaziabad (IN)

(73) Assignee: FREESCALE SEMICONDUCTOR, INC., Austin, TX (US)

(21) Appl. No.: 12/714,528

(22) Filed: Feb. 28, 2010

(51) Int. Cl. G11C 17/00; G11C 7/00

(52) U.S. Cl. 365/104; 365/189.15

(57) ABSTRACT

A read-only memory for storing two data values using a single transistor includes a word line, a pair of bit lines, a select line, and a transistor to store data corresponding to each bit lines in the pair of bit lines. The gate terminal of the transistor is connected to the word line, a first diffusion terminal of the transistor is connected to one of the first bit line and the select line based on the first data value and a second diffusion terminal of the transistor is connected to one of the second bit line and the select line based on the second data value.

### BACKGROUND OF THE PRESENT INVENTION

The present invention relates generally to read-only memory (ROM), and more specifically, to a system and method for storing and sensing two bits using a single transistor in a ROM.

Read-only memories are used extensively to store data in various computational and data processing systems. Two key design objectives of ROMS are to achieve high storage density and fast access speed.

With various developments in semiconductor fabrication processes in recent years, it has become possible to reduce the size of ROMS for a given storage capacity and thus, leading to improved storage density. However, due to inherent constraints imposed by fabrication processes, miniaturization seems to have reached its practical limitations. Further, as the size of a memory cell is reduced, process variations increase significantly, and thus, large timing margins are required to compensate for the process variations. This affects the access speed of the read-only memory. Thus, the two key design objectives are contradictory and conventional systems can strive only to achieve an optimum trade-off between storage density and access speed.

A conventional ROM includes a matrix of transistors, multiple word lines and multiple bit lines. Each transistor is capable of acting as a storage element for one bit of data. Further, each transistor is uniquely addressable using a combination of a word line and a bit line. As described hereinafter, a combination of a bit line and a word line decoding one bit of data stored in a ROM is referred to as a memory cell.

FIG. 1 is a schematic diagram illustrating a conventional 2×2 memory array 100. The memory array 100 includes four memory cells M₁₁, M₁₂, M₂₁, and M₂₂, two bit lines 102 and 104, two word lines 106 and 108, ground lines 110, and transistors 112-118. In the drawing, the memory array 100 is coded to store data values 0 and 0 in the memory cells M₁₁ and M₁₂, which are addressable by selecting the word line 106 along with the bit lines 102 and 104 respectively. The memory array 100 also is coded to store data values 1 and 0 in the memory cells M₂₁ and M₂₂, which are addressable by selecting the word line 108 along with the bit lines 102 and 104 respectively.

Each transistor 112-118 has three terminals, including a gate, and first and second diffusion terminals. In various implementations, the first diffusion terminal may be a drain terminal and the second diffusion terminal may be a source terminal or vice-versa. The gate terminals of the transistors 112 and 114 are connected to the word line 106 and similarly, the gate terminals of the transistors 116 and 118 are connected to the word line 108.

In order to store the data values shown in FIG. 1, the first diffusion terminals of the transistors 112 and 116 are connected to the bit line 102, the second diffusion terminal of the transistor 112 is connected to the ground line 110, and the second diffusion terminal of the transistor 116 is kept floating. Similarly, the first diffusion terminals of the transistors 114 and 118 are connected to the bit line 104, and the second diffusion terminals of the transistors 114 and 118 are connected to the ground lines 110.

When reading the data stored in the memory array 100, a bit line is selected and pre-charged using a voltage source for a predefined time interval after which the voltage source is cut-off. Thereafter, a word line is activated for a predefined time interval. Subsequently, the charge on the bit line is sensed using a sensing circuit (not shown).

For example, to read the data stored in the memory cell M₁₁, the bit line 102 is pre-charged and thereafter, the word line 106 is activated. The word line 106 activates the gate terminal of the transistor 112 and thus, the transistor 112 is turned on. The bit line 102 is discharged through the transistor 112 to the ground line 110. Subsequently, when the bit line 102 is sensed using the sensing circuit, a low voltage is detected and thus, logic 0 is read as the data value stored in the memory cell M₁₁. On the other hand, when reading the data stored in the memory cell M₂₁, the bit line 102 does not discharge through the transistor 116 (as the second diffusion terminal is not connected to the ground line 110) and hence, the sensing circuit detects a high voltage, and accordingly, logic 1 is read as the data value stored in the memory cell M₂₁.

In accordance with the conventional techniques, the size of the memory cell has been decreased in order to achieve improved storage density. However, as the memory cell becomes smaller, the process variations increase significantly. Accordingly, a large timing margin is required to adequately compensate for these process variations, which affects the access speed of the ROM. If the memory cell is kept large enough so there is little process variation and better access speed, the storage density is negatively impacted. Thus, process variation is a key factor in limiting the memory cell size and hence, storage density enhancement also is limited. Thus, there is a need for improving the storage density of a ROM without exacerbating process variations and negatively impacting access speed.

### BRIEF DESCRIPTION OF THE DRAWINGS

The following detailed description of the preferred embodiments of the present invention will be better understood when read in conjunction with the appended drawings. The present invention is illustrated by way of example, and not limited by the accompanying figures, in which like references indicate similar elements.

FIG. 1 is a schematic circuit diagram illustrating a conventional 2×2 memory array;

FIGS. 2A-2D are schematic circuit diagrams for storing two data values using a single transistor in a memory array in accordance with an embodiment of the present invention;

FIGS. 3A-3R are schematic circuit diagrams for implementing a 2×2 memory array using two transistors in accordance with an embodiment of the present invention;

FIG. 4 is a schematic circuit diagram for a 4×2 memory array in accordance with an embodiment of the present invention;

FIG. 5 is a schematic block diagram of a ROM in accordance with an embodiment of the present invention;

FIG. 6 is a schematic circuit layout of the column multiplexing unit in a ROM in accordance with an embodiment of the present invention;

FIG. 7 is a flowchart illustrating a method for reading one or more data values stored in a ROM in accordance with an embodiment of the present invention; and

FIGS. 8A and 8B are a flowchart illustrating a method for reading one or more data values stored in a ROM in accordance with another embodiment of the present invention.

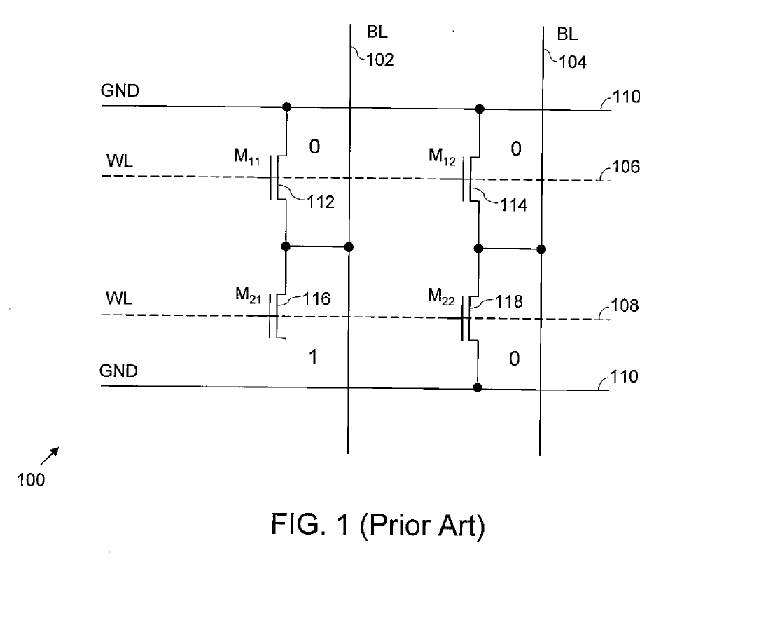

### DETAILED DESCRIPTION OF THE PRESENT INVENTION

The detailed description of the appended drawings is intended as a description of the currently preferred embodiments of the present invention, and is not intended to represent the only form in which the present invention may be practiced. It is to be understood that the same or equivalent functions may be accomplished by different embodiments that are intended to be encompassed within the spirit and scope of the present invention.

In accordance with an embodiment of the present invention, a read-only memory (ROM) for storing two data values using a single transistor and a system and method for sensing the same is provided. The ROM includes a first bit line, a second bit line, a word line, a transistor and a select line. The transistor is configured to store a first data value corresponding to the first bit line and a second data value corresponding to the second bit line. A gate terminal of the transistor is connected to the word line, a first diffusion terminal is connected to the first bit line based on the first data value, and a second diffusion terminal is connected to the second bit line based on the second data value.

In accordance with another embodiment of the present invention, a ROM for storing a plurality of data values includes a plurality of word lines, a plurality of bit lines, a plurality of transistors, and a plurality of select lines. The plurality of bit lines is grouped into one or more pairs of bit lines. Each pair of bit lines includes at least a first bit line and a second bit line. The plurality of select lines provides a predefined voltage level during a reading operation. In one embodiment, each select line is shared by at least two pairs of bit lines and in an alternative embodiment each pair of bit lines is associated with a unique select line.

Each transistor is associated with exactly one word line and exactly one pair of bit lines. A gate terminal of each the transistor is connected to the associated word line. A first diffusion terminal of each transistor is connected to one of the first bit line and a select line selected from the plurality of select lines based on the first data value. A second diffusion terminal of each transistor is connected to one of the second bit line and the select line based on the second data value.

In accordance with yet another embodiment of the present invention, a method for retrieving a data value stored in a memory cell is disclosed. A first bit line corresponding to the memory cell is selected and switched to a first voltage level. A second bit line and a select line corresponding to the memory cell are switched to a second voltage level. A word line corresponding to the memory cell is activated for a predefined time interval. Subsequently, a voltage level on the first bit line is sensed to read the data stored in the memory cell.

In accordance with still another embodiment of the present invention, a system for performing a read operation to retrieve a data value stored in a memory cell of a ROM includes an address decoding unit for identifying a first bit line, a word line, and a select line corresponding to a memory cell. The system also includes a column multiplexing unit (hereinafter “column mux”) for selecting first and second bit lines corresponding to the memory cell. The column mux facilitates switching the first bit line to a first voltage level and the second bit line to a second voltage level. A sensing unit is provided to sense a voltage level on the first bit line.

Various embodiments of the present invention provide an improved system and method of storing data in a ROM. The system and method facilitate storing two data values using a single transistor. Thus, the present invention facilitates significant improvement in storage density of the ROM without unduly reducing the size of the memory cell. Accordingly, the process variations are minimal and the access speed is improved. The ROM of the present invention has reduced leakage current and hence, improved power efficiency.

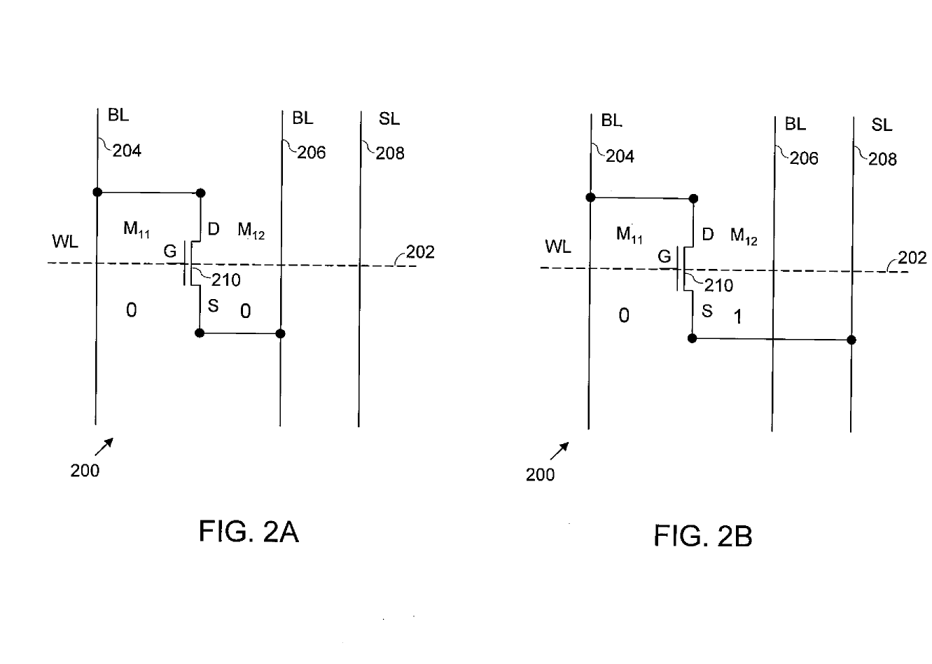

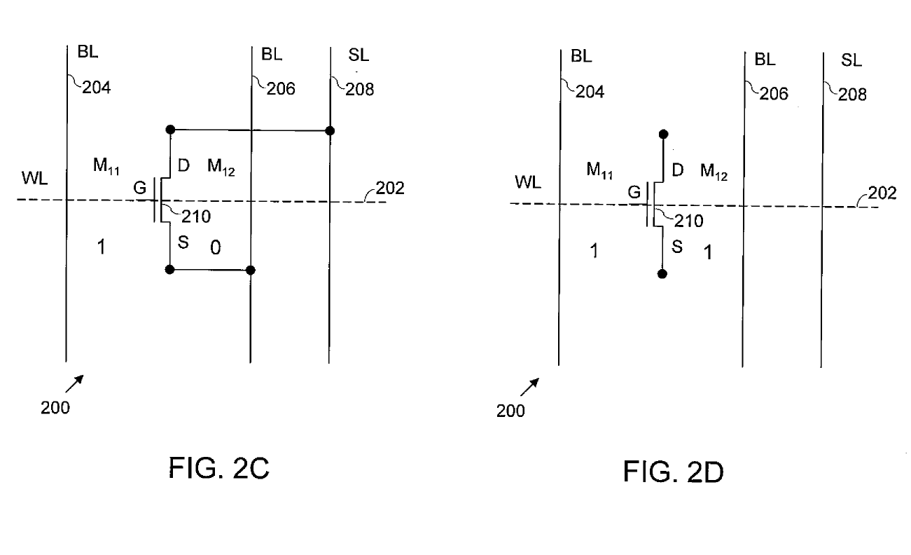

Referring now to FIGS. 2A to 2D, schematic circuit diagrams of a memory array 200 that has two memory cells formed from a single transistor is shown. FIGS. 2A to 2D show the various connections for the elements of the memory array 200 depending on the data values stored in the memory cells. That is, FIG. 2A corresponds to a stored value of “00” in the memory array 200, FIG. 2B corresponds to a stored value of “01”, FIG. 2C a stored value of “10”, and FIG. 2D for a stored value of “11”. The memory array 200 includes two memory cells M₁₁ and M₁₂, one word line 202, two bit lines 204 and 206, and one select line 208. (Note, the word line 202 is shown used a dashed line only to make it easier to distinguish for a viewer). The memory cell M₁₁ is addressable using a combination of the word line 202 and the bit line 204. Similarly, the memory cell M₁₂ is addressable using a combination of the word line 202 and the bit line 206.

As mentioned above, the memory array 200 also includes a transistor, in this case, transistor 210. The transistor 210 has three terminals namely, a gate terminal, a first diffusion terminal and a second diffusion terminal. The gate terminal of the transistor 210 is connected to the word line 202. In an embodiment of the present invention, the first diffusion terminal is a drain terminal and the second diffusion terminal is a source terminal. The present invention will hereinafter be described in accordance with this embodiment. In an alternative embodiment of the present invention, the first diffusion terminal is a source terminal and the second diffusion terminal is a drain terminal.

In various embodiments of the present invention, the memory array 200 may be coded using various ROM programming techniques such as via programming and metal programming.

In the schematic circuit diagram shown in FIG. 2A, the memory array 200 is coded to store data value “00” in the memory cells M₁₁ and M₁₂. In order to store these data values, the first and the second diffusion terminals of the transistor 210 are connected to the bit lines 206 and 204 respectively.

In an embodiment of the present invention, when reading the data stored in the memory array 200, a first bit line is selected and pre-charged using a voltage source for a predefined time interval after which the voltage source is cut-off. A second bit line and a select line associated with the first bit line are maintained at ground potential. Thereafter, a word line is activated for a predefined time interval. Subsequently, the charge on the bit line is sensed using a sensing circuit (not shown in the figure). If a high voltage is sensed, the data value is read as logic 1 and if a low voltage is sensed, the data value is read as logic 0.

For example, to read the data stored in memory cell M₁₁, the bit line 204 is pre-charged and the bit line 206 and the select line 208 are kept at ground potential. Thereafter, the word line 202 is activated. The word line 202 activates the gate terminal of the transistor 210 and thus, the transistor 210 is turned on. The bit line 204 is discharged through the transistor 210 to the bit line 206. Subsequently, when the bit line 204 is sensed using the sensing circuit, a low voltage is detected and thus, logic 0 is read as the data value stored in the memory cell M₁₁.

Similarly, to read the data stored in the memory cell M₁₂, the bit line 206 is pre-charged while the bit line 204 and the select line 208 are kept at ground potential. Thereafter, the word line 202 is activated. The word line 202 activates the gate terminal of the transistor 210 and thus, the transistor 210 is turned on. The bit line 206 is discharged through the transistor 210 to the bit line 204. Subsequently, when the bit line 206 is sensed using the sensing circuit, a low voltage is detected and thus, logic 0 is read as the data value stored in the memory cell M₁₂.

In an alternative embodiment of the present invention, when reading the data stored in the memory array 200, a first bit line is selected and maintained at ground potential. A second bit line and a select line associated with the first bit line are pre-charged using a voltage source for a predefined time interval after which the voltage source is cut-off. Thereafter, a word line is activated for a predefined time interval. In another embodiment of the present invention, the word line may be activated after initiating pre-charging of the second bit line and the select line. Subsequently, the charge on the first bit line is sensed using a sensing circuit. If a high voltage is sensed, the data value is read as logic 0. Alternatively, if a low voltage is sensed, the data value is read as logic 1.

In the schematic circuit diagram shown in FIG. 2B, the memory array 200 is coded to store data value “01” in the memory cells M₁₁ and M₁₂. In order to store these data values, the first diffusion terminal of the transistor 210 is connected to the bit line 204 and the second diffusion terminal of the transistor 210 is connected to the select line 208. Then, when reading the data value stored in memory cell M₁₂, bit line 206 does not discharge through the transistor 210 (as it is not connected to the transistor 210) and hence, the sensing circuit detects a high voltage, and accordingly, logic 1 is read as the data value stored in the memory cell M₂₁.

In the schematic circuit diagram shown in FIG. 2C, the memory array 200 is coded to store data value “10” in the memory cells M₁₁ and M₁₂. In order to store these two data values, the first diffusion terminal of the transistor 210 is connected to the select line 208 and the second diffusion terminal of the transistor 210 is connected to the bit line 206.

In the schematic circuit diagram shown in FIG. 2D, the memory array 200 is coded to store data value “11” in the memory cells M₁₁ and M₁₂. In order to store these two data values, the first and the second diffusion terminals of the transistor 210 are kept floating. In an alternative embodiment of the present invention, the first and the second diffusion terminals of the transistor 210 may be connected to the select line 208.

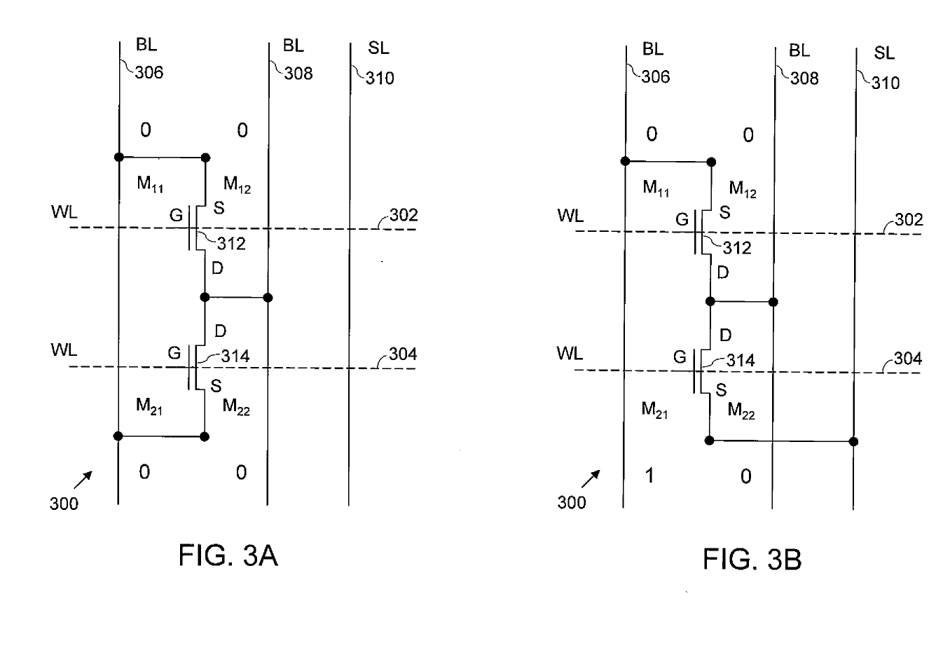

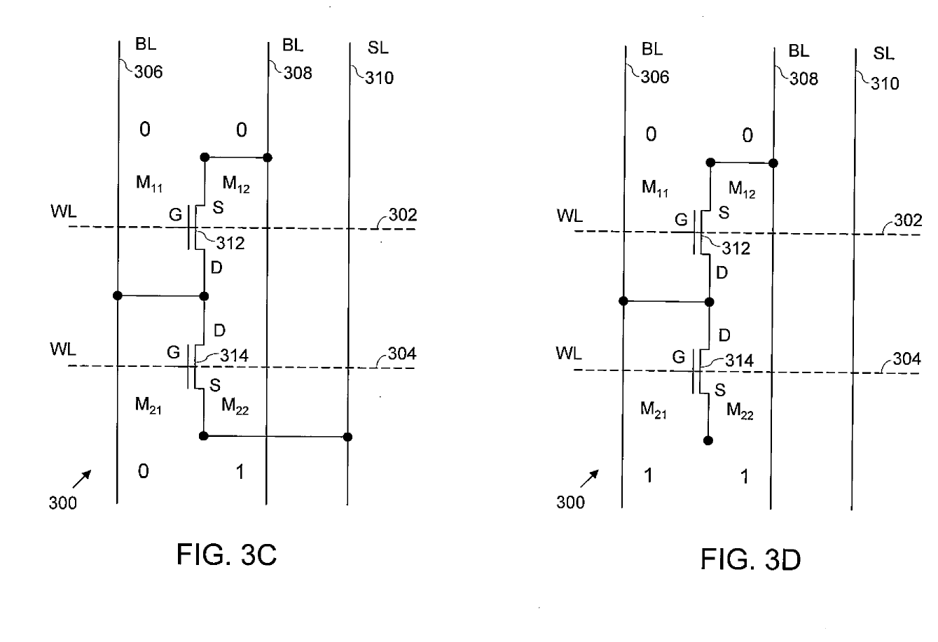

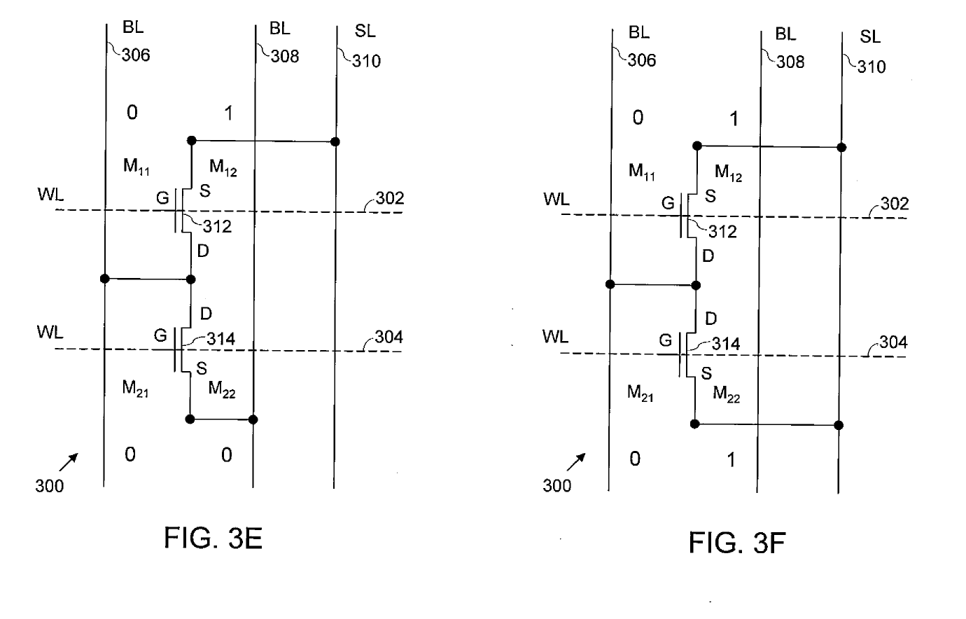

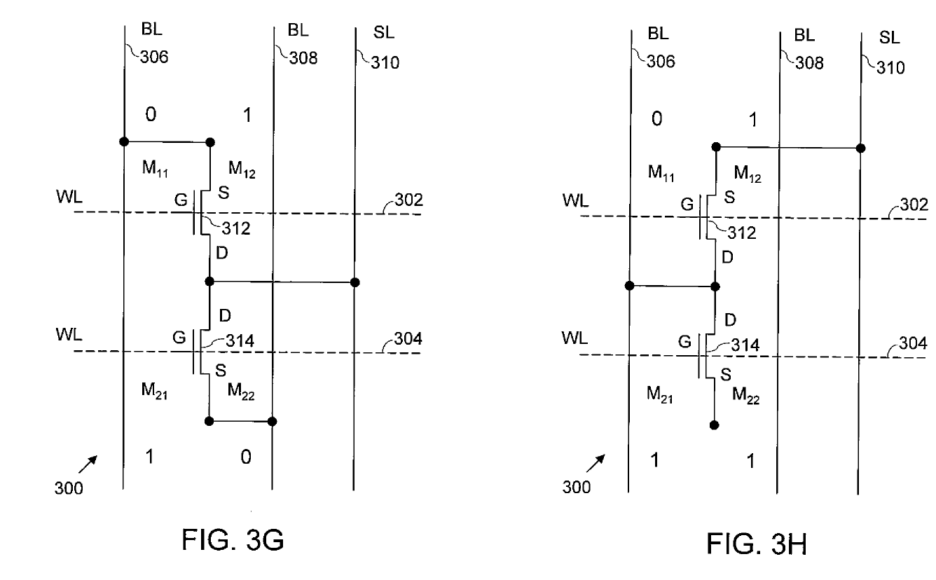

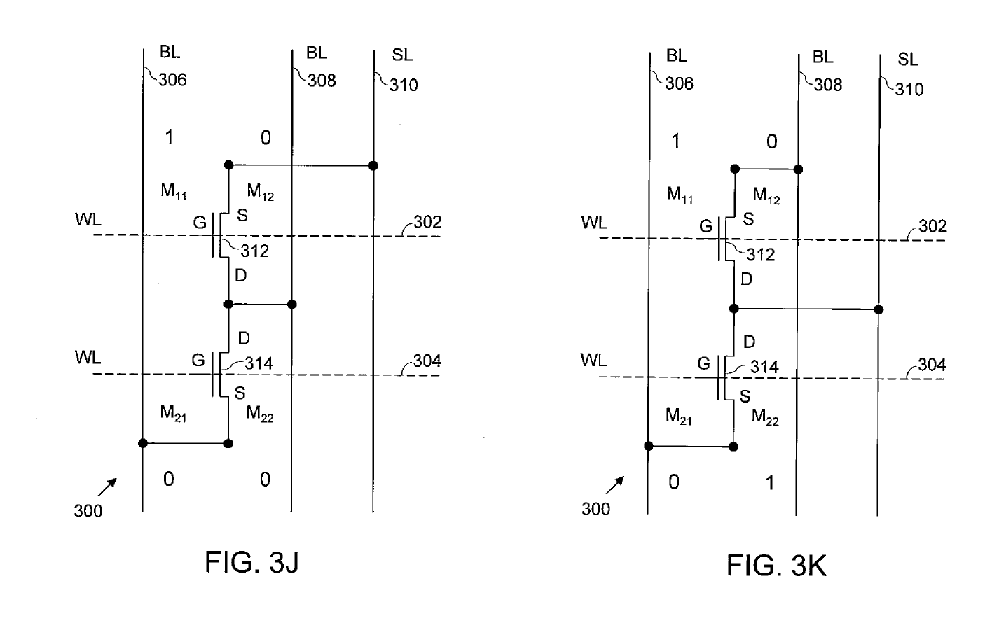

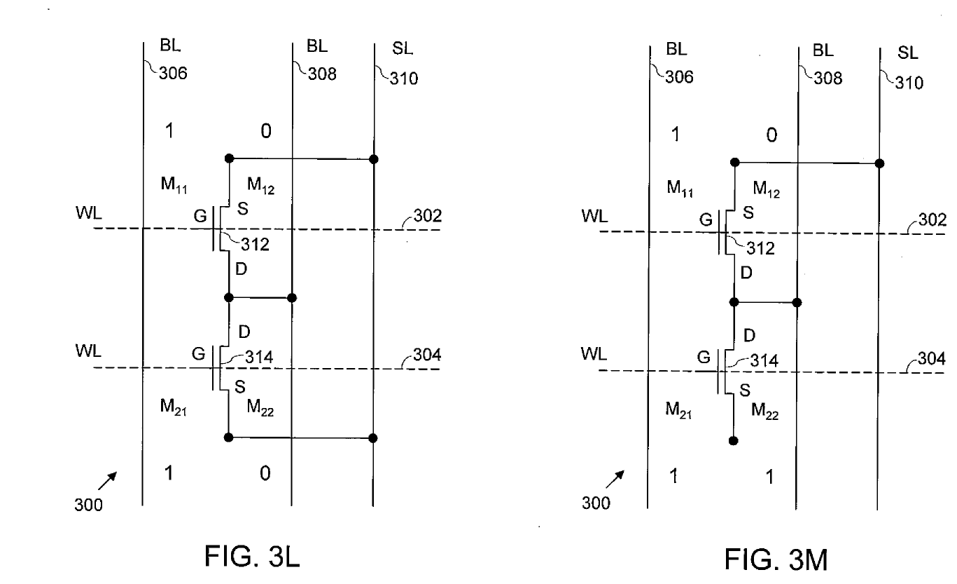

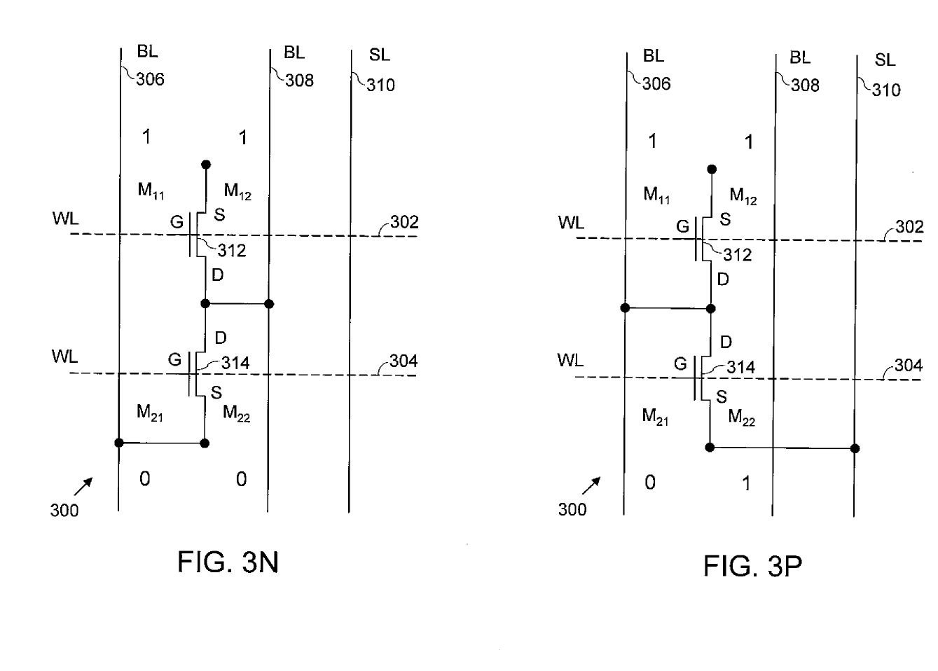

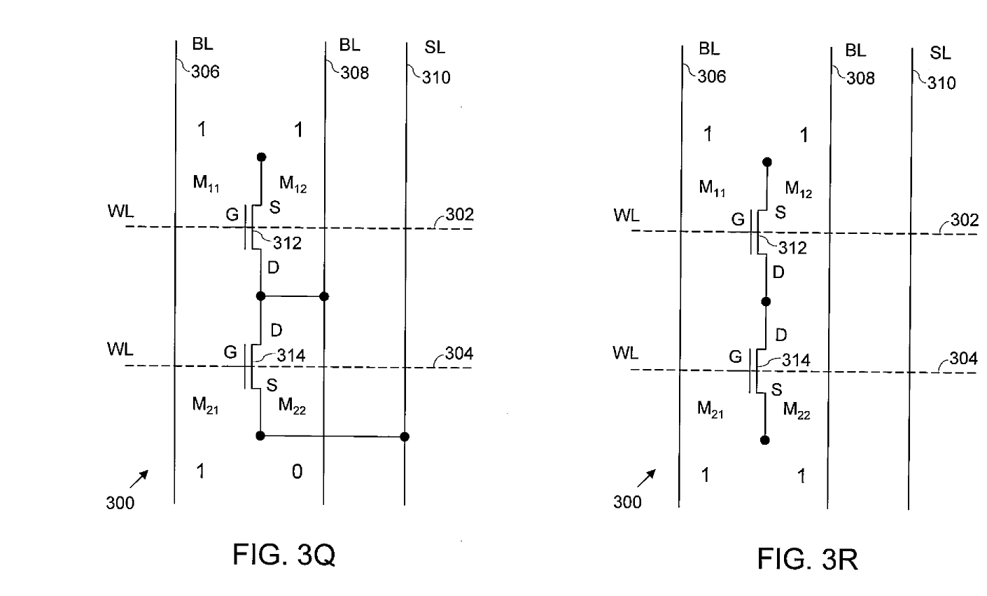

Referring now to FIGS. 3A to 3R, schematic circuit diagrams showing the various connections for implementing a 2×2 memory array 300 using two transistors in accordance with an embodiment of the present invention are shown. The memory array 300 includes four memory cells M₁₁, M₁₂, M₂₁, and M₂₂, and therefore is capable of storing sixteen (16) different values (e.g., “0000” to “1111”). FIGS. 3A to 3D illustrate the configurations for data values “0000” to “0011”; FIGS. 3E to 3H for data values “0100” to “0111”, FIGS. 3J to 3M for data values “1000” to “1011”, and finally FIGS. 3N to 3R for data values “1100” to “1111”.

The memory array 300 includes two word lines 302 and 304, two bit lines 306 and 308, and one select line 310. The memory cells M₁₁ and M₁₂ are addressable using a combination of the word line 302 with the bit lines 306 and 308, respectively. Similarly, the memory cells M₁₁ and M₂₂ are addressable using a combination of the word line 304 with the bit lines 306 and 308 respectively.

The memory array 300 also includes transistors 312 and 314. Each of the transistors 312 and 314 has three terminals namely, a gate terminal, a first diffusion terminal and a second diffusion terminal. The gate terminals of the transistor 312 and 314 are connected to the word lines 302 and 304 respectively. In an embodiment of the present invention, the first diffusion terminal is a drain terminal and the second diffusion terminal is a source terminal. The present invention will hereinafter be described in accordance with this embodiment. The first diffusion terminals of the transistors 312 and 314 are shared. However, in alternative embodiments of the present invention, the first diffusion terminals of the transistors 312 and 314 may not be shared.

In FIG. 3A, the memory array 300 is coded to store data values 0 and 0 in the memory cells M₁₁ and M₁₂ and data values 0 and 0 in the memory cells M₂₁ and M₂₂. In order to store these data values, the first diffusion terminals of the transistors 312 and 314 are connected to the bit line 308, and the second diffusion terminals of the transistors 312 and 314 are connected to the bit line 306.

In various embodiments of the present invention, the data stored in the memory array 300 is read in a manner described in conjunction with FIG. 2. For example, to read the data stored in memory cell M₁₁, the bit line 306 is pre-charged. The bit line 308 and the select line 310 are kept at ground potential. Thereafter, the word line 302 is activated. The word line 302 activates the gate terminal of the transistor 312 and thus, the transistor 312 is turned on. The bit line 306 is discharged through the transistor 312 to the bit line 308. Subsequently, when the bit line 306 is sensed using a sensing circuit, a low voltage is detected and thus, logic 0 is read as the data value stored in the memory cell M₁₁. The other memory cells of the memory array 300 may be similarly read.

As mentioned above, FIGS. 3B through 3R illustrate circuit diagrams for storing various combinations of four data values in the memory array 300, and detailed description of each figure is akin to the description of that for FIG. 3A and as discussed above as regards FIGS. 2A to 2D. With reference to FIG. 3D, it is noted that in an alternative embodiment of the present invention, the second diffusion terminal of the transistor 314 is connected to the bit line 306. In standby mode, when the memory array 300 is not being accessed, the bit lines 306 and 308 and the select line 310 are maintained at ground potential. This assists in reducing leakage current.

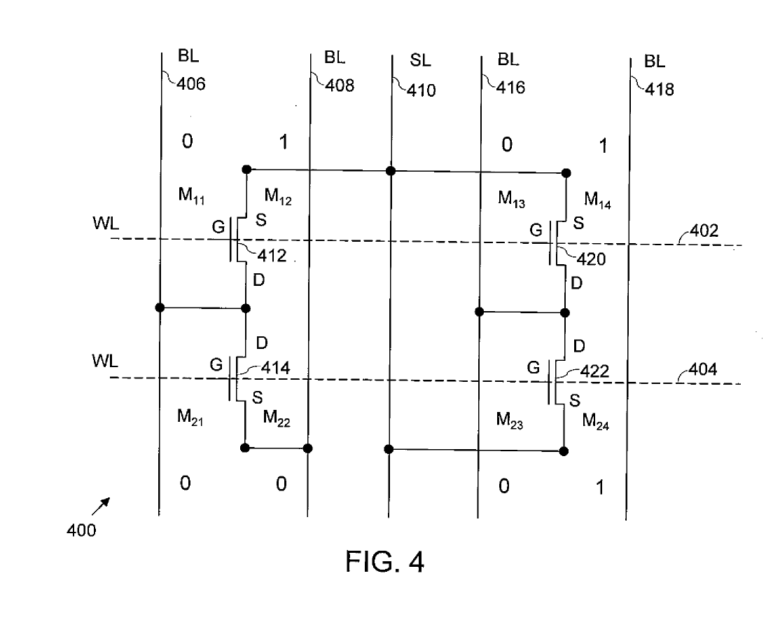

Referring now to FIG. 4, an exemplary schematic circuit diagram of a 4×2 memory array 400 in accordance with an embodiment of the present invention is shown. The memory array 400 includes eight memory cells M₁₁ through M₂₄, two word lines 402 and 404, four bit lines 406, 408, 416, and 418, one select line 410, and four transistors 412, 414, 420, and 422. In the case of multiple bit lines, adjacent bit lines are grouped in pairs and two pairs of bit lines share a single select line. Thus, the first pair of bit lines includes bit lines 406 and 408, and the second pair of bit lines includes bit lines 416 and 418, and each of these bit line pairs shares the select line 410. In an alternative embodiment, each pair of bit lines is associated with a unique select line.

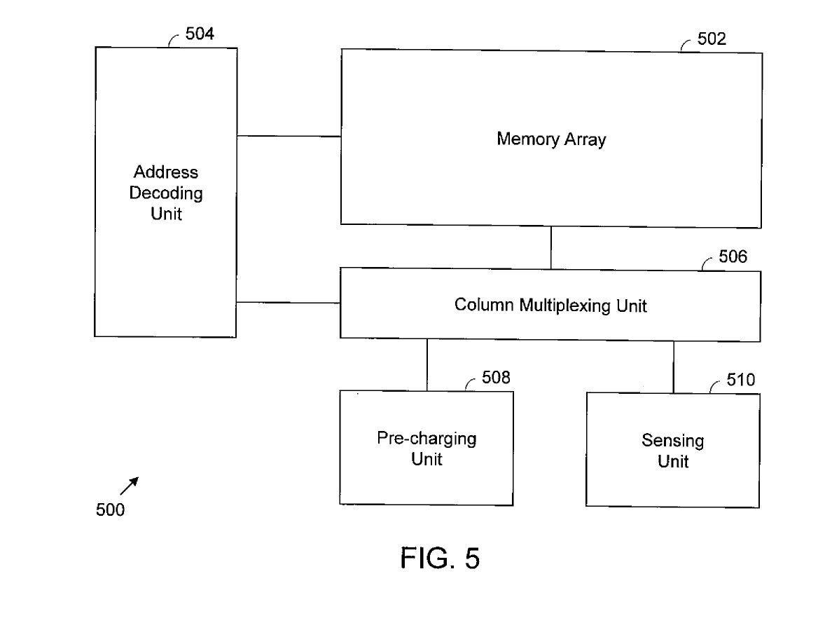

Referring now to FIG. 5, a schematic block diagram of a read-only memory 500 in accordance with an embodiment of the present invention is shown. The read-only memory 500 includes a memory array 502, an address-decoding unit 504, a column multiplexing unit 506, a pre-charging unit 508 and a sensing unit 510.

The memory array 502 is implemented in accordance with the various embodiments of the present invention explained in conjunction with FIGS. 2 through 4. The address decoding unit 504 functions to identify a bit line and a word line to be selected to read a memory cell o the memory array 502. The address decoding unit 504 is connected directly to the memory array 502 to activate a desired word line. However, for selecting a bit line, the address decoding unit 504 is connected by way of the column multiplexing unit 506. The column multiplexing unit 506 functions to select a desired bit line and simultaneously, to maintain another bit line associated with the desired bit line at ground potential.

The column multiplexing unit 506 is connected to the pre-charging unit 508 and the sensing unit 510. During a read operation, the column multiplexing unit 506 provides access to the desired bit line to the pre-charging unit 508 for a predefined time interval. Subsequently, the column multiplexing unit 506 provides access to the desired bit line to the sensing unit 510. The sensing unit 510 senses the voltage on the desired bit line and in accordance with the sensed voltage level determines the value of the data stored in the memory cell. In one embodiment of the present invention, a differential sensing scheme is used to sense the voltage level of the memory cell. However, any suitable sensing scheme such as an inverter-sensing scheme may be used. The sensing technique used may be either single-ended or dual-ended.

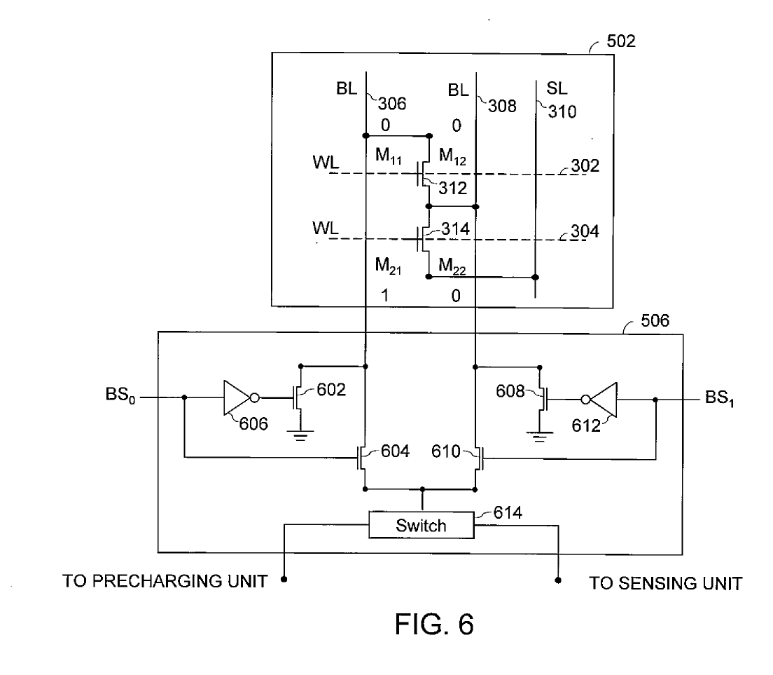

Referring now to FIG. 6, a schematic circuit diagram of the column multiplexing unit or column mux 506 corresponding to the memory array 300 in accordance with an embodiment of the present invention is shown. The column mux 506 includes four transistors 602, 604, 608, and 610; two inverters 606 and 612; and a switch 614. The column mux 506 receives address data corresponding to a bit line to be selected from the address decoding unit 504. Signals BS₀ and BS₁ are received from the address decoding unit 504, which for FIG. 6 correspond to the bit lines 306 and 308 respectively. It should be noted that during any read operation only one bit line will be selected. Accordingly, if BS₀ is high voltage (logic 1) then BS₁ will be low voltage (logic 0) and vice-versa. The switch 614 facilitates switching between the pre-charging unit 508 and the sensing unit 510 in accordance with the sensing scheme.

For example, when the bit line 306 is to be selected, BS₀ is high (logic 1) and BS₁ is low (logic 0). Thus, transistor 604 is turned on while the output of the inverter 606 keeps the transistor 602 turned off. On the other hand, BS₁ keeps the transistor 610 turned off while the output of the inverter 612 turns the transistor 608 on. Therefore, the bit line 306 is selected while the bit line 308 is maintained at ground potential. The select line 310 is kept at ground potential.

After the bit line 306 has been selected, the bit line 306 is pre-charged for a first predefined time interval and thereafter, the word line is activated for a second predefined time interval. Subsequently, the voltage level at the bit line 306 is sensed to read the data value stored in a desired memory cell.

In an alternative embodiment of the present invention, the bit line 306 is selected and the bit line 308 and the select line 310 are pre-charged with the help of the pre-charging unit 508. Thus, during a read operation of memory cell _{M11}, the bit line 306 is selected. The bit line 308 and the select line 310 associated with the bit line 306 are pre-charged using the pre-charging unit 508. Thereafter, the word line 302 is activated for a predefined time interval. Subsequently, the charge on the bit line 306 is sensed using a sensing circuit (not shown in the figure). If a high voltage value is sensed, the data value is read as logic 0. Alternatively, if a low voltage is sensed, the data value is read as logic 1.

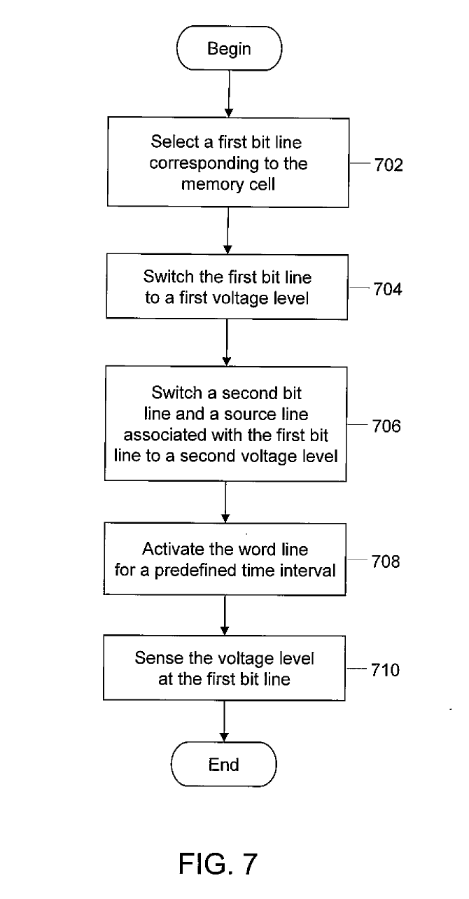

Referring now to FIG. 7, a flowchart depicting a method for reading a data value stored in a ROM in accordance with an embodiment of the present invention is shown.

Beginning with step 702, a first bit line corresponding to a memory cell is selected. Next, at step 704, the first bit line is switched to a first voltage level for a predefined time. At step 706, a select line and a second bit line, associated with the first bit line are identified and switched to a second voltage level. Then at step 708, a word line corresponding to the memory cell is activated for a predefined time interval. Finally, at step 710, the voltage level on the first bit line is sensed to determine a data value stored in the memory cell.

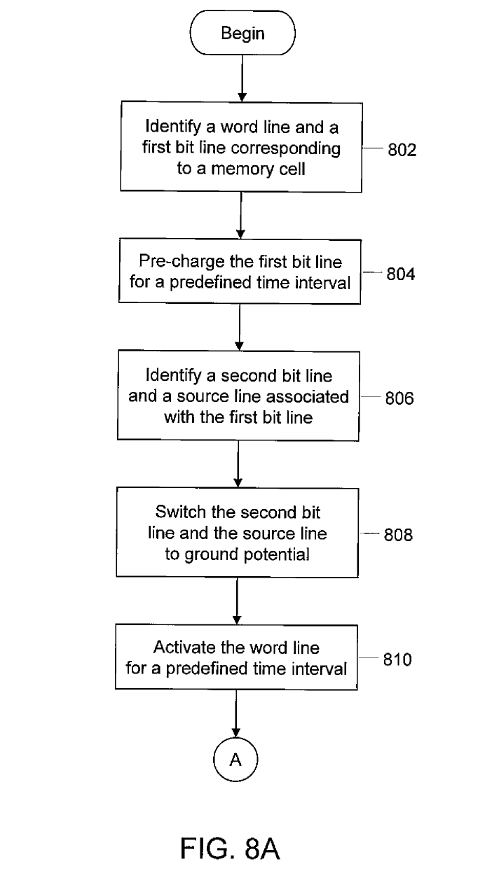

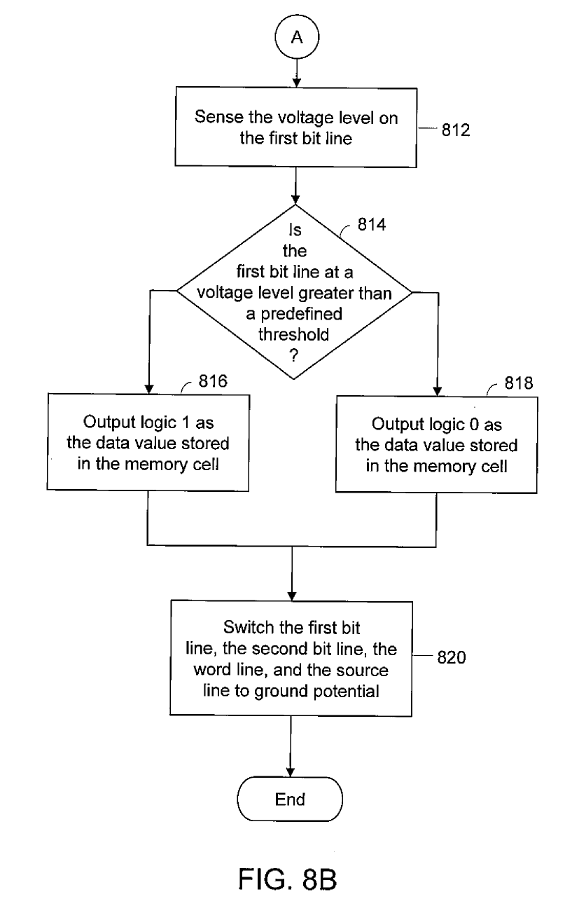

Referring now to FIGS. 8A and 8B, a flowchart of a method for reading a data value stored in a ROM in accordance with an another embodiment of the present invention is shown.

Beginning at step 802, a word line and a first bit line corresponding to a memory cell are identified. At step 804, the first bit line is pre-charged using a voltage source. The voltage source is cut-off after charging the first bit line for a predefined time. At step 806, a select line and a second bit line associated with the first bit line are identified, and at step 808, the select line and the second bit line are switched to ground potential.

At step 810, the word line is activated for a predefined time period. The word line, in turn, turns on a transistor associated with the memory cell. At step 812, the voltage level on the first bit line is sensed using a sensing unit. At step 814, it is determined if the voltage level on the first bit line exceeds a predefined voltage level. If the voltage level exceeds the predefined voltage level, then the data value is read as logic 1 at step 816. Alternatively, if the voltage level is below the predefined voltage level, then the data value is read as logic 0 at step 818. Finally, at step 820, the first bit line, the second bit line, the word line, and the select line are switched to ground potential.

Various embodiments of the present invention provide an improved system and method for storing two data values using a single transistor in a read-only memory and a system and method of sensing the same. Thus, the present invention facilitates significant improvement in storage density of the read-only memory without unduly reducing the size of the memory cell. In accordance with various embodiments of the present invention, it is possible to design a memory cell array with a specific substrate area and storage capacity using memory cells of about thrice the minimum memory cell size used in conventional technologies. Accordingly, the effect of process variations is greatly reduced and the access speed is much faster. The present invention facilitates use of any suitable sensing scheme such as differential sensing and inverter sensing. Further, the sensing technique may be either single-ended or dual-ended. The ROM as described herein also has low leakage current and therefore good power efficiency.

While various embodiments of the present invention have been illustrated and described, it will be clear that the present invention is not limited to these embodiments only. Numerous modifications, changes, variations, substitutions, and equivalents will be apparent to those skilled in the art, without departing from the spirit and scope of the present invention, as described in the claims.

What is claimed is:

1. A read-only memory including at least two memory cells, the read-only memory comprising:
a word line;
a first bit line for retrieving a first data value corresponding to the word line from a first one of the memory cells;
a second bit line for retrieving a second data value corresponding to the word line from a second one of the memory cells;
a select line for facilitating a read operation of the read-only memory; and
a transistor configured to store the first and second data values in the first and second memory cells, wherein a gate terminal of the transistor is connected to the word line, a first diffusion terminal of the transistor is connected to one of the first bit line and the select line based on at least one of the first and the second data values, and a second diffusion terminal of the transistor is connected to one of the second bit line and the select line based on at least one of the first and second data values.

2. The read-only memory of claim 1, wherein the first diffusion terminal of the transistor is connected to the first bit line if the first data value is 0, to the select line if the first data value is 1 and the second data value is 0, and is floating if both the first and second data values are 1.

3. The read-only memory of claim 1, wherein the second diffusion terminal of the transistor is connected to the second bit line if the second data value is 0, to the select line if the second data value is 1 and the first data value is 0, and is floating if both the first and second data values are 1.

4. The read-only memory of claim 1, wherein the select line is kept at a predefined voltage level.

5. The read-only memory of claim 4, wherein the predefined voltage level is ground potential.

6. The read-only memory of claim 1, wherein the transistor is one of an N-MOS transistor and an N-FET transistor.

7. A method for performing a read operation to retrieve a data value stored in a memory cell of a read-only memory, comprising:
selecting a first bit line corresponding to the memory cell;
switching the first bit line to a first voltage level;
switching a select line and a second bit line to a second voltage level, wherein the first and second bit lines comprise a pair of associated bit lines, and the select line is associated with the pair of bit lines;
activating a word line corresponding to the memory cell for a predefined time interval; and
sensing a voltage level on the first bit line.

8. The method for performing a read operation of claim 7, wherein the first voltage level is a pre-charge voltage level, the first bit line is switched to the first voltage level for a predefined interval of time, and the second voltage level is a ground voltage level.

9. The method for performing a read operation of claim 8, wherein the select line is constantly maintained at ground potential.

10. The method for performing a read operation of claim 7, wherein the first voltage level is a ground voltage level, the second voltage level is a pre-charge voltage level, and the second bit line is switched to the second voltage level for a predefined interval of time.

11. The method for performing a read operation of claim 10, wherein the select line is constantly maintained at pre-charge voltage level.

12. A system for performing a read operation to retrieve a data value stored in one of a plurality of memory cells of a read-only memory, wherein the data value is retrieved from the one memory cell using one of a plurality of word lines, one of a plurality of select lines, and at least one of a pair of bit lines associated with the memory cell, the system comprising:
an address decoding unit for identifying one of the bit lines of the bit line pair, the one word line, and the one select line corresponding to the memory cell to be read;
a column multiplexing unit for selecting between a first bit line and a second bit line of the pair of bit lines, wherein the column multiplexing unit facilitates switching the first bit line to a first voltage level and the second bit line to a second voltage level; and
a sensing unit for sensing a voltage level on the first bit line.

13. The system for performing a read operation of claim 12, further comprising a pre-charge unit for switching the first bit line to the first voltage level.

14. The system for performing a read operation of claim 13, wherein the second voltage level is a ground potential.

15. The system for performing a read operation of claim 13, wherein the select line is maintained at a ground potential.

16. The system for performing a read operation of claim 12, further comprising a pre-charge unit for switching the second bit line to the second voltage level.

17. The system for performing a read operation of claim 16, wherein the first voltage level is a ground potential.

18. The system for performing a read operation of claim 16, wherein the select line is maintained at the second voltage level.
